(19) United States
(12) Patent Application Publication
(10) Pub. No.: US 2025/0321154 A1
(43) Pub. Date: Oct. 16, 2025

(54) SUBSTRATE PROCESSING APPARATUS AND ABNORMALITY DETECTING METHOD OF SEALING MEMBER IN SUBSTRATE PROCESSING APPARATUS

(71) Applicant: Tokyo Electron Limited, Tokyo (JP)

(72) Inventor: Yuki WATANABE, Kumamoto (JP)

(73) Assignee: Tokyo Electron Limited, Tokyo (JP)

(21) Appl. No.: 19/173,936

(22) Filed: Apr. 9, 2025

(30) Foreign Application Priority Data
Apr. 12, 2024 (JP) 2024-064385

(51) Int. Cl. G01M 3/38; G06T 7/00

(52) U.S. Cl. CPC G01M 3/38; G06T 7/0008; G06T 2207/30164

(57) ABSTRACT

A substrate processing apparatus includes a processing container, a sealing member, a lighting unit, and an image capturing unit. The processing container includes a first member and a second member, and moves the second member to be connected with the first member to form therein a processing space. The sealing member is provided to one of the first member and the second member, and is in contact with another of the first member and the second member in a case where the first member and the second member are connected with each other. The lighting unit irradiates light towards the sealing member on the one of the first member and the second member in a state where the first member and the second member are separated from each other. The image capturing unit captures the sealing member that receives the light irradiated from the lighting unit.

### CROSS-REFERENCE TO RELATED APPLICATION

This application is based upon and claims the benefit of priority of the prior Japanese Patent Application No. 2024-064385, filed on Apr. 12, 2024, the entire contents of which are incorporated herein by reference.

### FIELD

Exemplary embodiments disclosed herein relate to a substrate processing apparatus and an abnormality detecting method of a sealing member in the substrate processing apparatus.

### BACKGROUND

Conventionally, in a substrate processing apparatus that is configured to execute a supercritical drying process for drying a substrate by using supercritical fluid, a sealing member has been used in order to secure airtightness in a processing container (see Japanese Patent Application Laid-open No. 2013-131729, for example).

The present disclosure provides a technology for appropriately detecting abnormality in a sealing member.

A substrate processing apparatus according to one aspect of embodiments includes a processing container, a sealing member, a lighting unit, and an image capturing unit. The processing container includes a first member and a second member that can be connected with each other, and moves the second member to be connected with the first member to form therein a processing space in which a substrate is processed. The sealing member is provided to one of the first member and the second member, and is in contact with another of the first member and the second member in a case where the first member and the second member are connected with each other. The lighting unit irradiates light towards the sealing member on the one of the first member and the second member in a state where the first member and the second member are separated from each other. The image capturing unit captures the sealing member that receives the light irradiated from the lighting unit.

### SUMMARY

A substrate processing apparatus according to one aspect of the present disclosure includes: a processing container that includes a first member and a second member that can be connected with each other, and moves the second member to be connected with the first member to form therein a processing space in which a substrate is processed; a sealing member that is provided to one of the first member and the second member, and is in contact with another of the first member and the second member in a case where the first member and the second member are connected with each other; a lighting unit that irradiates light towards the sealing member on the one of the first member and the second member in a state where the first member and the second member are separated from each other; and an image capturing unit that captures the sealing member that receives the light irradiated from the lighting unit.

### BRIEF DESCRIPTION OF DRAWINGS

FIG. 1 is a diagram illustrating a configuration of a substrate processing system according to a first embodiment;

FIG. 2 is a diagram illustrating a configuration of a liquid processing unit according to the first embodiment;

FIG. 3 is an external perspective view illustrating a configuration of a drying process unit according to the first embodiment;

FIG. 4 is a cross-sectional view illustrating a configuration of the drying process unit according to the first embodiment;

FIG. 5 is a cross-sectional view illustrating a configuration of the drying process unit according to the first embodiment;

FIG. 6 is a side view illustrating a configuration of a lid body in the drying process unit;

FIG. 7 is a block diagram illustrating a configuration of a control device according to the first embodiment;

FIG. 8 is a diagram illustrating one example of an abnormality detecting process according to the first embodiment;

FIG. 9 is a flowchart illustrating a processing procedure for substrate processing to be executed by the substrate processing system according to the first embodiment;

FIG. 10 is a flowchart illustrating one example of a specific procedure for a sealing member abnormality detecting process according to the first embodiment;

FIG. 11 is a cross-sectional view illustrating a configuration of a drying process unit according to a second embodiment;

FIG. 12 is a block diagram illustrating a configuration of a control device according to the second embodiment;

FIG. 13 is a flowchart illustrating one example of a specific procedure for a sealing member abnormality detecting process according to the second embodiment;

FIG. 14 is a cross-sectional view illustrating a configuration of a drying process unit according to a third embodiment;

FIG. 15 is a cross-sectional view illustrating one example of a state where a wafer is housed in a processing container of the drying process unit;

FIG. 16 is a schematic diagram illustrating a configuration example of an ozonated water processing unit according to a fourth embodiment; and

FIG. 17 is a diagram illustrating a state where a processing container of the ozonated water processing unit according to the fourth embodiment is separated.

### DESCRIPTION OF EMBODIMENTS

Hereinafter, modes (hereinafter, may be referred to as “embodiments”) for implementing a substrate processing apparatus and an abnormality detecting method of a sealing member in the substrate processing apparatus will be described in detail with reference to the accompanying drawings. In addition, the illustrative embodiments disclosed below are not intended to limit the disclosed technology. Note that any of the embodiments can be appropriately combined with each other within a consistency range. Hereinafter, the same reference symbol is provided to the same part in the following embodiment so as to omit duplicated explanation.

For convenience of explanation, in the following drawings to be mentioned later, an orthogonal coordinate system may be used in which an X-axis direction, a Y-axis direction, and a Z-axis direction are defined which are perpendicular to one another, and further the positive Z-axis direction is a vertical upward direction. Additionally, a rotational direction around a vertical axis as rotational center may be referred to as a θ direction.

Furthermore, expressions of “constant”, “perpendicular”, “vertical”, and “parallel” used in the following embodiments are not necessarily identical to “constant”, “perpendicular”, “vertical”, and “parallel” strictly. In other words, the above-mentioned expressions may include a divergence caused by, for example, manufacturing accuracy, installation accuracy, and the like.

### First Embodiment

### Configuration of Substrate Processing System

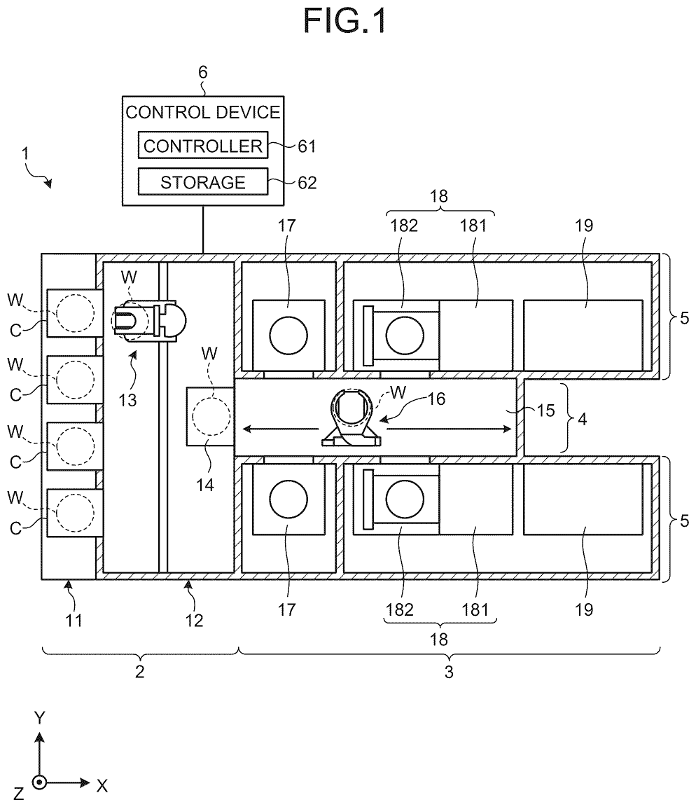

A configuration of a substrate processing system according to a first embodiment will be explained with reference to FIG. 1. FIG. 1 is a diagram illustrating a configuration of the substrate processing system according to the first embodiment.

As illustrated in FIG. 1, a substrate processing system 1 includes a carry-in/out station 2 and a processing station 3. The carry-in/out station 2 and the processing station 3 are adjacently arranged to each other.

The carry-in/out station 2 includes a carrier placing section 11 and a transfer section 12. A plurality of carriers C is placed in the carrier placing section 11, each of which accommodates therein a plurality of semiconductor wafers (hereinafter, may be referred to as “wafers W”) in a horizontal state.

The transfer section 12 is adjacently arranged to the carrier placing section 11. A transfer device 13 and a delivery unit 14 are arranged in the transfer section 12.

The transfer device 13 includes a wafer holding mechanism that is configured to hold the wafer W. The transfer device 13 is capable of moving in a horizontal direction and/or a vertical direction, and further of turning around a vertical axis so as to transfer the wafer W between the carrier C and the delivery unit 14 by using the wafer holding mechanism.

The processing station 3 is adjacently arranged to the transfer section 12. The processing station 3 includes a transfer block 4 and a plurality of processing blocks 5 (herein, two processing blocks are exemplified).

The transfer block 4 includes a transfer area 15 and a transfer device 16. For example, the transfer area 15 is a rectangular parallelepiped region that extends along an alignment direction (namely, X-axis direction) of the carry-in/out station 2 and the processing station 3. In the transfer area 15, the transfer device 16 (one example of substrate transfer device) is arranged.

The transfer device 16 includes a wafer holding mechanism configured to hold the wafer W. The transfer device 16 is capable of moving in a horizontal direction and a vertical direction and further is capable of turning around a vertical axis so as to transfer the wafer W between the delivery unit 14 and the plurality of processing blocks 5 by using the wafer holding mechanism.

The plurality of processing blocks 5 is adjacently arranged to the transfer area 15 on both sides of the transfer area 15. Specifically, the plurality of processing blocks 5 is arranged on one side (namely, side of positive Y-axis direction) and the other side (namely, side of negative Y-axis direction) of the transfer area 15 in a direction (namely, Y-axis direction) that is perpendicular to a direction (namely, X-axis direction) in which the carry-in/out station 2 and the processing station 3 are aligned.

Each of the processing blocks 5 includes a liquid processing unit 17, a drying process unit 18 (one example of substrate processing apparatus), and a supply unit 19.

The liquid processing unit 17 is configured to execute a cleaning process for cleaning an upper surface that is a pattern-formed surface of the wafer W. The liquid processing unit 17 is configured to execute a liquid-film forming process for forming a liquid film on a surface (namely, upper surface) of the cleaning-processed wafer W. A configuration of the liquid processing unit 17 will be mentioned later.

The drying process unit 18 is configured to execute a supercritical drying process on the liquid-film forming processed wafer W. Specifically, the drying process unit 18 brings the liquid-film forming processed wafer W into contact with processing fluid in a supercritical state, so as to dry the above-mentioned wafer W.

The drying process unit 18 includes a processing area 181 in which a supercritical drying process is executed, and a carry-in/carry-out area 182 via which the wafer W is transferred between the transfer block 4 and the processing area 181. The processing area 181 and the carry-in/carry-out area 182 are arranged side-by-side along the transfer area 15. A specific configuration of the drying process unit 18 will be mentioned later.

The supply unit 19 supplies processing fluid to the drying process unit 18. Specifically, the supply unit 19 includes a supply device group including a flowmeter, a flow controller, a back pressure valve, a heater, and the like; and a housing accommodating therein the supply device group. In the first embodiment, the supply unit 19 supplies CO₂ to the drying process unit 18 as processing fluid.

The substrate processing system 1 includes a control device 6. The control device 6 is a computer, for example, so as to include a controller 61 and a storage 62.

The controller 61 includes a micro-computer including a Central Processing Unit (CPU), a Read Only Memory (ROM), an input/output port, etc.; and various circuits. The CPU of the above-mentioned micro-computer reads out and executes a program stored in the ROM, so as to control operations of the transfer device 16, the liquid processing unit 17, the drying process unit 18, and the like.

The above-mentioned program may be one that is stored in a computer-readable recording medium and further is installed into the storage 62 of the control device 6 from the recording medium. As the computer-readable recording medium, a hard disk (HD), a flexible disk (FD), a compact disk (CD), a magnet-optical disk (MO), a memory card, or the like may be employed.

The storage 62 is realized by a semiconductor memory element such as a RAM and a Flash Memory; a storage device such as a hard disk and an optical disk; etc.

### Configuration of Liquid Processing Unit

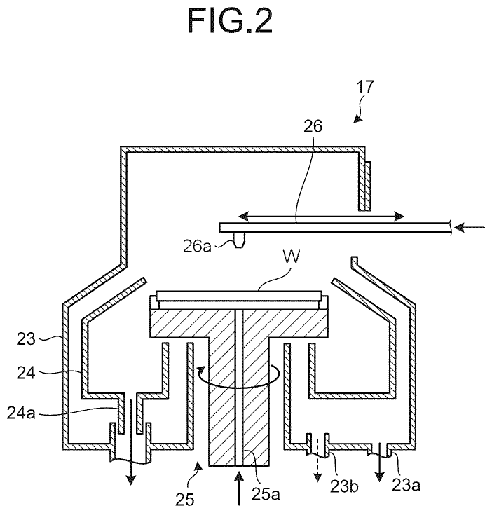

Next, a configuration of the liquid processing unit 17 will be explained with reference to FIG. 2. FIG. 2 is a diagram illustrating a configuration of the liquid processing unit 17 according to the first embodiment. The liquid processing unit 17 is configured as a sheet-type cleaning device that cleans the wafer W one-by-one by spin cleaning, for example.

As illustrated in FIG. 2, the liquid processing unit 17 causes a wafer holding mechanism 25 arranged in an outer chamber 23 forming a processing space to substantially and horizontally hold the wafer W. The wafer holding mechanism 25 is rotated around a vertical axis so as to rotate the wafer W. The liquid processing unit 17 causes a nozzle arm 26 to enter the above of the rotating wafer W, and further causes a chemical liquid nozzle 26a arranged on a leading end of the above-mentioned nozzle arm 26 to supply chemical liquid, rinse liquid, and the like in a predetermined order, so as to execute a cleaning process on a surface of the wafer W.

In the liquid processing unit 17, a gas supplying route 25a is formed in the wafer holding mechanism 25. The liquid processing unit 17 supplies gas supplied from the above-mentioned gas supplying route 25a, for example, inert gas such as nitrogen gas, to a central portion of a back surface of the wafer W.

In the cleaning process, for example, particles and organic contaminants are first removed by SC1 liquid (namely, mixed solution of ammonia and hydrogen peroxide) that is alkaline chemical liquid, and then rinse cleaning is executed by using DeIonized Water (hereinafter, may be referred to as “DIW”) that is rinse liquid. Next, a natural oxide film is removed by Diluted HydroFluoric acid (hereinafter, may be referred to as “DHF”) that is acidic chemical liquid, and then rinse cleaning with the use of DIW is executed.

The above-mentioned various chemical liquids are received by the outer chamber 23 and/or an inner cup 24 arranged in the outer chamber 23 to be discharged from a drain port 23a arranged in a bottom portion of the outer chamber 23 and a drain port 24a arranged in a bottom portion of the inner cup 24. Furthermore, atmosphere in the outer chamber 23 is discharged from an exhaust port 23b arranged in a bottom portion of the outer chamber 23.

A liquid-film forming process is executed after a rinsing process of the cleaning process. Specifically, the liquid processing unit 17 supplies IPA liquid to a front surface and a back surface of the wafer W while causing the wafer holding mechanism 25 to rotate. Thus, DIW remaining on both surfaces of the wafer W is replaced with IPA.

In this case, the liquid processing unit 17 supplies gas to a central portion of a back surface of the wafer W from the gas supplying route 25a. The gas supplied to a central portion of a back surface of the wafer W flows towards a peripheral portion of the back surface of the wafer W along the back surface of the wafer W. Thus, it is possible to prevent IPA supplied to a front surface of the wafer W from going around to a back surface of the wafer W during a liquid-film forming process in the liquid processing unit 17. Next, the liquid processing unit 17 gently stops rotation of the wafer holding mechanism 25.

The liquid-film forming processed wafer W is delivered to the transfer device 16 by a delivery mechanism provided in the wafer holding mechanism 25 in a state where a liquid film of IPA liquid is formed on a front surface of the wafer W to be carried out from the liquid processing unit 17. The liquid film formed on the wafer W prevents occurrence of pattern collapse due to evaporation of liquid on an upper surface of the wafer W during transfer of the wafer W from the liquid processing unit 17 to the drying process unit 18 or during an operation for carrying into the drying process unit 18.

### Configuration of Drying Process Unit

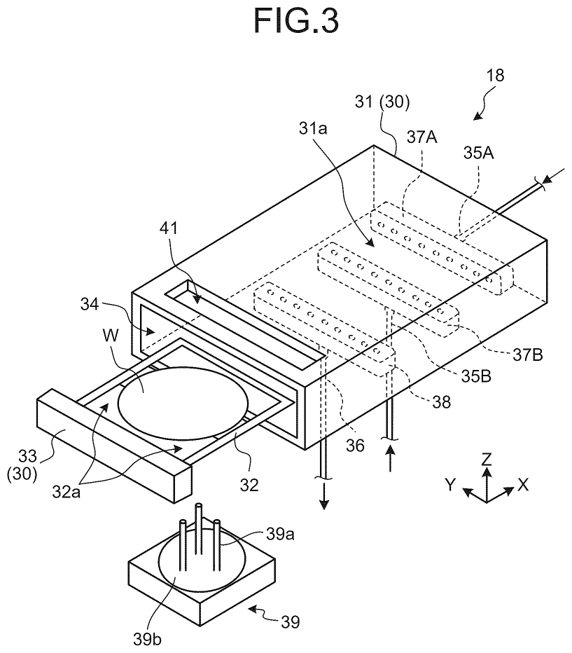

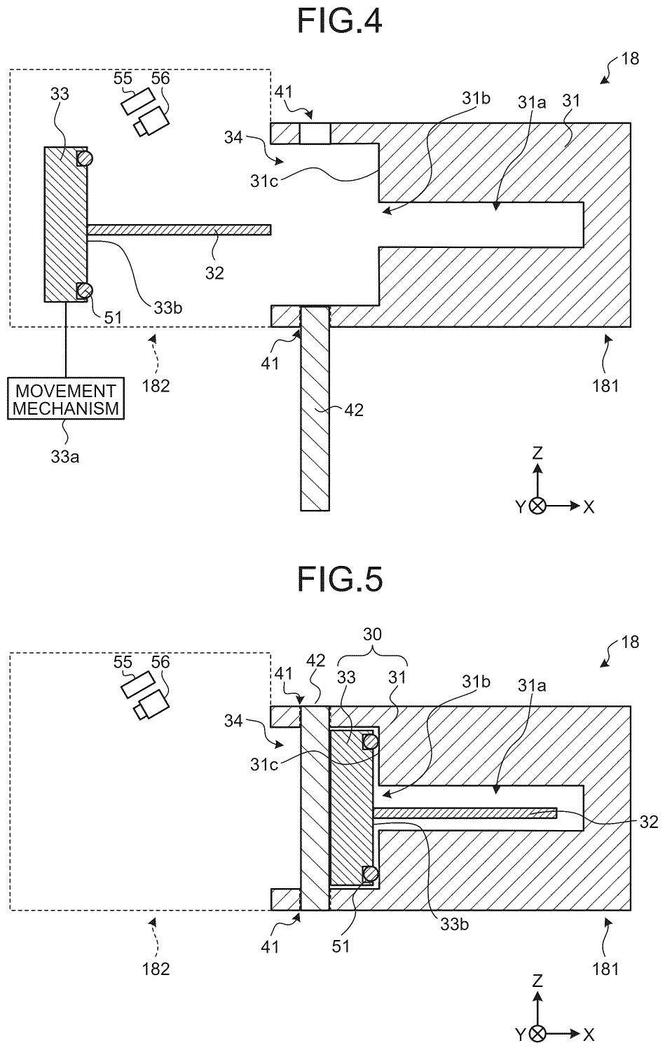

Next, a configuration of the drying process unit 18 will be explained with reference to FIG. 3 to FIG. 6. FIG. 3 is an external perspective view illustrating a configuration of the drying process unit 18 according to the first embodiment. FIGS. 4 and 5 are cross-sectional views illustrating a configuration of the drying process unit 18 according to the first embodiment. Note that FIG. 4 illustrates a state where a lid body 33 is arranged in the carry-in/carry-out area 182 in the drying process unit 18, and further FIG. 5 illustrates a state where the lid body 33 is arranged in the processing area 181.

As illustrated in FIG. 3 to FIG. 5, the drying process unit 18 includes a processing container 30, a holding member 32, and a lifter 39. The processing container 30 includes a housing member 31 (one example of first member) and the lid body 33 (one example of second member) that are capable of being in connect with each other and are capable of separating from each other to be configured to form therein a sealed processing space 31a.

The housing member 31 is a housing-shaped housing in which the processing space 31a is formed therein, which is capable of housing therein the wafer W having a diameter 300 mm, for example, and further is a pressure vessel that is capable of forming a high-pressure environment of approximately 16 MPa to 20 MPa, for example. The housing member 31 is arranged in the processing area 181 (see FIG. 1), and a supercritical drying process is executed in the processing space 31a of the housing member 31. In the processing space 31a, a transfer port 31b (see FIG. 4 and FIG. 5) is adjacently formed to the processing space 31a, via which the wafer W is transferred. In a side surface of the housing member 31, an opening 34 is formed for carrying in/out therethrough the holding member 32, the lid body 33, and the wafer W. The opening 34 causes the processing space 31a and the carry-in/carry-out area 182 to communicate with each other.

The lid body 33 supports the holding member 32. The lid body 33 is connected with a movement mechanism 33a so as to horizontally move between the processing area 181 and the carry-in/carry-out area 182 by the movement mechanism 33a. Thus, the lid body 33 opens/closes the transfer port 31b of the housing member 31. The lid body 33 moves into the processing area 181, and thus the holding member 32 is arranged in the housing member 31 and the lid body 33 closes the transfer port 31b. On the other hand, the lid body 33 moves into the carry-in/carry-out area 182, and thus the holding member 32 is arranged in the carry-in/carry-out area 182 and the lid body 33 opens the transfer port 31b.

The holding member 32 horizontally holds the wafer W to be processed. The holding member 32 is a rectangular-parallelepiped frame body in a plan view, for example, and further supports a peripheral portion of the wafer W from the below so as to hold the wafer W. The holding member 32 is provided to the lid body 33.

Supply ports 35A and 35B and a discharge port 36 are provided to a wall part of the housing member 31. Each of the supply ports 35A and 35B and the discharge port 36 is connected to a supply flow path and a discharge flow path through which supercritical fluid flows, which are respectively arranged on an upstream side and a downstream side of the drying process unit 18.

In the housing-shaped housing member 31, the supply port 35A is connected with a side surface opposite to the opening 34. The supply port 35B and the discharge port 36 are connected with a bottom surface of the housing member 31. Note that the double supply ports 35A and 35B and the single discharge port 36 are illustrated in FIG. 3; however, the number of the supply ports 35A and 35B and the number of the discharge ports 36 are not limited thereto.

The processing space 31a is provided with fluid supplying headers 37A and 37B and a fluid discharging header 38. A plurality of openings is formed in each of the fluid supplying headers 37A and 37B and the fluid discharging header 38.

The fluid supplying header 37A is connected to the supply port 35A, and further is adjacently arranged to a side surface on an opposite side of the opening 34 in the processing space 31a. A plurality of openings formed in the fluid supplying header 37A faces the opening 34.

The fluid supplying header 37B is connected to the supply port 35B, and further is arranged in a central portion of a bottom surface in the processing space 31a. A plurality of openings formed in the fluid supplying header 37B faces upward.

The fluid discharging header 38 is connected to the discharge port 36, and further is arranged close to the transfer port 31b on the bottom surface of the processing space 31a. A plurality of openings formed in the fluid discharging header 38 faces upward.

The fluid supplying headers 37A and 37B supply processing fluid to the processing space 31a. The fluid discharging header 38 leads and discharges processing fluid in the processing space 31a to the outside of the housing member 31. Note that supercritical fluid to be discharged to the outside of the housing member 31 via the fluid discharging header 38 includes IPA liquid that has dissolved in supercritical fluid from a surface of the wafer W.

The drying process unit 18 discharges processing fluid in the processing space 31a via the fluid discharging header 38 while supplying heated processing fluid from the fluid supplying headers 37A and 37B to the processing space 31a. A damper, which adjusts a discharging amount of processing fluid from the processing space 31a, is arranged on a discharge path of processing fluid, and the damper adjusts a discharging amount of processing fluid such that a pressure in the processing space 31a is adjusted to be a desired one. Thus, a supercritical state of processing fluid is maintained in the processing space 31a. Hereinafter, processing fluid in a supercritical state may be referred to as “supercritical fluid”.

In the processing space 31a, laminar flow of supercritical fluid is formed, which flows in a predetermined direction in surroundings of the wafer W. For example, the laminar flow of supercritical fluid flows over the wafer W along an upper surface of the wafer W towards an upper portion of the transfer port 31b from the fluid supplying header 37A. Furthermore, the laminar flow of supercritical fluid changes a flowing direction thereof into downward in an upper portion of the transfer port 31b so as to flow through the vicinity of the transfer port 31b towards the fluid discharging header 38.

In the example of the above-mentioned laminar flow, in the processing space 31a, the laminar flow of supercritical fluid passes through an opening 32a that is formed between the wafer W and the lid body 33 in the holding member 32.

In a case where being in contact with supercritical fluid in a high-pressure state (for example, 16 MPa), IPA liquid remaining on a pattern-formed surface (namely, upper surface) of the wafer W gradually dissolves into the supercritical fluid to be replaced with the supercritical fluid. Thus, gaps in a pattern goes into a state being filled with the supercritical fluid.

Next, the drying process unit 18 reduces a pressure in the processing space 31a from a high-pressure state to the atmospheric pressure. Thus, the supercritical fluid having filled gaps in a pattern changes into processing fluid that is in a normal state, in other words, a gas state.

As described above, the drying process unit 18 replaces IPA liquid remaining on a pattern-formed surface with supercritical fluid and then returns the supercritical fluid to processing fluid in a gas state so as to remove the IPA liquid from the pattern-formed surface and further to dry the pattern-formed surface.

Compared with liquid (for example, IPA liquid), supercritical fluid has a lower viscosity and has a higher ability to dissolve liquid, and further there presents no interface between supercritical fluid and liquid/gas that is in an equilibrium state with respect to the supercritical fluid. Thus, by employing the supercritical drying process, it is possible to dry liquid without being affected by surface tension. In other words, it is possible to prevent pattern collapse during a drying process.

Note that in the embodiment, IPA liquid is employed for liquid to prevent drying and further CO₂ is employed for processing fluid; however, liquid other than IPA may be employed for the liquid to prevent drying and fluid other than CO₂ may be employed for the processing fluid.

The lifter 39 is arranged in the carry-in/carry-out area 182. The lifter 39 includes a plurality of lifter pins 39a and a support body 39b that is connected with lower ends of the plurality of lifter pins 39a so as to support the plurality of lifter pins 39a.

The lifter 39 is turned/lifted by a turn/lift mechanism (not illustrated). Specifically, the lifter 39 turns/lifts between a standby position and a carry-in/carry-out position where the wafer W is transferred between the lifter pins 39a and the transfer device 16. The standby position is a position below the lid body 33 and the holding member 32 so as not to interfere with the lid body 33 or the holding member 32.

Herein, a sealing mechanism of the processing space 31a will be explained with reference to FIG. 4 and FIG. 5. As illustrated in FIG. 4 and FIG. 5, in the housing member 31, a penetration hole 41 is formed, which vertically penetrates a part thereof close to the opening 34.

The drying process unit 18 includes a pressing member 42. As illustrated in FIG. 4, the pressing member 42 is inserted into the penetration hole 41 that is formed below the opening 34. With the pressing member 42, a turn/lift mechanism (not illustrated) is connected, which moves the pressing member 42 along a vertical direction.

Operations of the pressing member 42 will be explained. As illustrated in FIG. 5, the drying process unit 18 first causes the movement mechanism 33a to move the holding member 32 and the lid body 33, so as to seal the processing space 31a by using the lid body 33. Next, the drying process unit 18 causes a turn/lift mechanism (not illustrated) to raise the pressing member 42 so as to insert the pressing member 42 into the penetration hole 41 formed above the opening 34.

The pressing member 42 presses the lid body 33 towards the processing space 31a against an inner pressure that is applied from supercritical fluid supplied to the processing space 31a. Thus, it is possible to maintain a state where the processing space 31a is sealed by the lid body 33.

The processing space 31a in which the wafer W is processed and the transfer port 31b via which the wafer W is transferred into the processing space 31a are formed in the housing member 31. The housing member 31 includes a surface 31c that surrounds the transfer port 31b so as to face the lid body 33.

The lid body 33 is inserted into the housing member 31 from the opening 34, and then is in contact with the surface 31c of the housing member 31 via a sealing member 51 to be connected with the housing member 31. For example, the sealing member 51 is made of resin, and is a member referred to as an “O-ring” formed in O-shaped in a cross-sectional view. The sealing member 51 is not limited to an O-ring, and may be a member referred to as a “U-seal” that is formed in U-shaped in a cross-sectional view, for example.

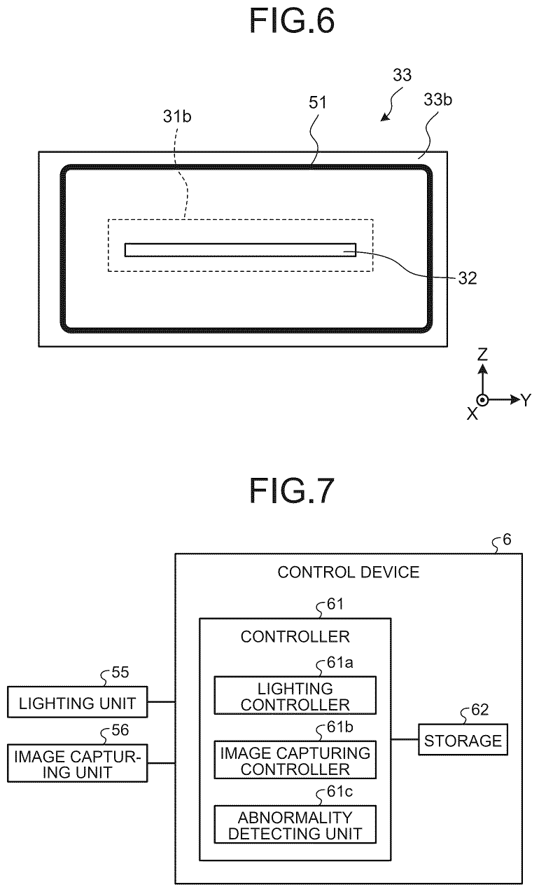

The sealing member 51 is provided to a surface 33b that faces the surface 31c of the housing member 31 in the lid body 33. FIG. 6 is a side view illustrating a configuration of the lid body 33 in the drying process unit 18. Note that FIG. 6 is a side view illustrating the surface 33b when viewed from the front, and for convenience of understanding, a position corresponding to the transfer port 31b of the housing member 31 is indicated by using dashed lines.

As illustrated in FIG. 6, in a side view, the sealing member 51 is arranged so as to surround the transfer port 31b and the holding member 32.

Returning to FIG. 4 and FIG. 5, the sealing member 51 will be continuously explained. The sealing member 51 arranged such that an inner surface located on a side of the transfer port 31b is communicated with the processing space 31a. Thus, the sealing member 51 gradually deteriorates due to an inner pressure that is applied by supercritical fluid supplied to the processing space 31a. As a deterioration state of the sealing member 51, for example, there is exemplified a state where a protruding portion is formed in a part of a peripheral edge of the sealing member 51 on an inner surface of the sealing member 51 located on a side of the transfer port 31b. The protruding portion protruding from a peripheral edge of the sealing member 51 is referred to as “fluff”, for example.

The drying process unit 18 further includes a lighting unit 55 and an image capturing unit 56.

The lighting unit 55 is arranged in the carry-in/carry-out area 182 so as to irradiate light towards the sealing member 51 on the lid body 33 in a state where the housing member 31 and the lid body 33 are separated from each other. For example, the lighting unit 55 irradiates light towards a predetermined region including the sealing member 51 on the surface 33b of the lid body 33.

The image capturing unit 56 is arranged in the carry-in/carry-out area 182 adjacently to the lighting unit 55 so as to capture the sealing member 51 that is receiving light irradiated from the lighting unit 55. For example, the image capturing unit 56 captures a predetermined region including the sealing member 51 on the surface 33b of the lid body 33, which receives light irradiated from the lighting unit 55.

As described above, the drying process unit 18 causes the image capturing unit 56 to capture the sealing member 51 while causing the lighting unit 55 to light the sealing member 51, so as to detect abnormality in the sealing member 51.

If the image capturing unit 56 executes capturing without using the lighting unit 55, an interface between the sealing member 51 on the surface 33b of the lid body 33 and a region around the sealing member 51 on the surface 33b is not clearly specified. Thus, there presents possibility that it is difficult to specify a protruding portion (namely, fluff) having occurred on a peripheral edge of the sealing member 51.

On the other hand, the drying process unit 18 according to the present embodiment causes the lighting unit 55 to light the sealing member 51 that is a capturing target of the image capturing unit 56. Thus, on the surface 33b of the lid body 33, it is possible to clarify an interface between the sealing member 51 and a region around the sealing member 51 on the surface 33b by using a contrast difference between the sealing member 51 and the region around the sealing member 51. As a result, a protruding portion (namely, fluff) protruding from a peripheral edge of the sealing member 51 can be easily specified, so that it is possible to appropriately detect abnormality in the sealing member 51.

In the embodiment, the sealing member 51 may have a color whose contrast ratio to that of the surface 33b of the lid body 33 is equal to more than a predetermined value in order to more clarify contrast difference between the sealing member 51 and a region around the sealing member 51 on the surface 33b of the lid body 33. For example, a color of the sealing member 51 may be white.

### Details of Detection Process

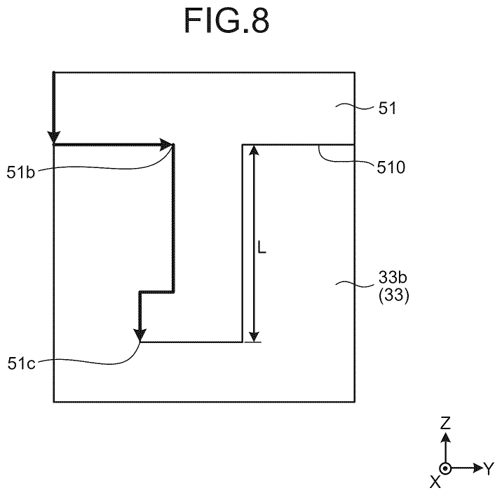

Next, details of a detection process for detecting abnormality in the sealing member 51 will be explained with reference to FIG. 7 and FIG. 8. FIG. 7 is a block diagram illustrating a configuration of the control device 6 according to the first embodiment. As illustrated in FIG. 7, the control device 6 includes the controller 61 and the storage 62.

The above-mentioned lighting unit 55 and the above-mentioned image capturing unit 56 are connected to the control device 6. Note that in addition to functional units illustrated in FIG. 7, the control device 6 may include various functional units provided to a well-known computer, such as various input devices and sound outputting devices.

The storage 62 is realized by a semiconductor memory element such as a RAM and a flash memory; and a storage device such as a hard disk and an optical disk. The storage 62 stores therein information to be used in various processes of the controller 61.

For example, the controller 61 is realized by a CPU, a Micro Processing Unit (MPU), a Graphics Processing Unit (GPU), or the like implementing a program stored in the storage 62 by using a RAM as an operation region.

For example, the controller 61 may be realized by an integrated circuit such as an Application Specific Integrated Circuit (ASIC) and a Field Programmable Gate Array (FPGA).

The controller 61 includes a lighting controller 61a, an image capturing controller 61b, and an abnormality detecting unit 61c.

The lighting controller 61a controls the lighting unit 55 so as to irradiate light from the lighting unit 55 towards the sealing member 51. The image capturing controller 61b controls the image capturing unit 56 to capture the sealing member 51 receiving light irradiated from the lighting unit 55 so as to acquire a captured image.

The abnormality detecting unit 61c receives a captured image acquired by the image capturing controller 61b, and further detects abnormality in the sealing member 51 on the basis of the above-mentioned captured image. Details of an abnormality detecting process to be executed by the above-mentioned abnormality detecting unit 61c will be explained with reference to FIG. 8.

FIG. 8 is a diagram illustrating one example of an abnormality detecting process according to the first embodiment. The abnormality detecting unit 61c first receives a captured image of the sealing member 51 that is acquired by the image capturing controller 61b, and further executes image processing on the received captured image by a predetermined method. For example, the abnormality detecting unit 61c acquires, for each pixel, a contrast difference that is a differential value of the brightness between adjacent pixel data in the captured image, and further detects a pixel whose above-mentioned contrast difference is equal to or more than a predetermined value as an edge in the image. In FIG. 8, the image-processed sealing member 51 and an image-processed region around the sealing member 51 on the surface 33b of the lid body 33 are indicated as a detection range.

In FIG. 8, on the surface 33b of the lid body 33, by searching in a vertical direction with respect to a detection range, an edge 510 is detected so as to be along an inner surface located on a side of the transfer port 31b of the sealing member 51. The above-mentioned edge 510 indicates a peripheral edge (hereinafter, may be referred to as “inner peripheral edge”) located on a side of the transfer port 31b of the sealing member 51. In other words, a captured image of the sealing member 51 according to the present embodiment includes the sealing member 51 as pixels having relatively high brightness values, and further includes a region around the sealing member 51 as pixels having relatively low brightness values, and thus the edge 510 coincides with an inner peripheral edge of the sealing member 51.

In FIG. 8, on the surface 33b of the lid body 33, a base end 51b of a protruding portion (namely, fluff) protruding from an inner peripheral edge of the sealing member 51 is detected by searching in a lateral direction with respect to the edge 510. On the surface 33b of the lid body 33, a terminal end 51c of the base end 51b of the protruding portion (namely, fluff) protruding from an inner peripheral edge of the sealing member 51 is detected by searching below the base end 51b. Thus, a protruding portion (namely, fluff) protruding from an inner peripheral edge of the sealing member 51 is specified.

Next, in a case where determining whether or not a length L of the specified protruding portion is equal to or more than a threshold and the length L is equal to or more than the threshold, the abnormality detecting unit 61c detects that abnormality has occurred in the sealing member 51.

In a case where detecting occurrence of abnormality in the sealing member 51, the abnormality detecting unit 61c outputs an alert. For example, the abnormality detecting unit 61c outputs an alert sound and/or a message indicating the fact that abnormality has occurred in the sealing member 51 to an output device (not illustrated).

As described above, in the present embodiment, abnormality in the sealing member 51 is detected on the basis of a captured image that is acquired by causing the image capturing unit 56 to capture the sealing member 51 while causing the lighting unit 55 to light the sealing member 51. Thus, it is possible to accurately specify a protruding portion (namely, fluff) protruding from a peripheral edge of the sealing member 51 with the use of a contrast difference between the sealing member 51 and a region around the sealing member 51. Therefore, according to the embodiment, it is possible to improve detection accuracy of abnormality in the sealing member 51.

In the present embodiment, in a case where a protruding portion protruding from an inner peripheral edge of the sealing member 51 is specified on the basis of the brightness in a captured image, and further in a case where the length L of the specified protruding portion is equal to more than a threshold; occurrence of abnormality in the sealing member 51 is detected. Thus, a state where fluff is formed on an inner peripheral edge of the sealing member 51 can be appropriately detected, so that it is possible to avoid a trouble due to the fluff of the sealing member 51 in advance.

In the present embodiment, in a case where occurrence of abnormality in the sealing member 51 is detected, an alert is output. Thus, it is possible to report occurrence of abnormality in the sealing member 51.

### Details of Substrate Processing

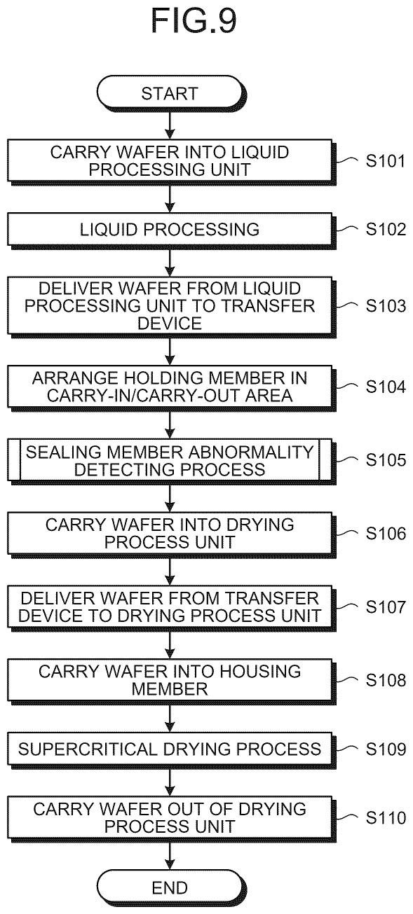

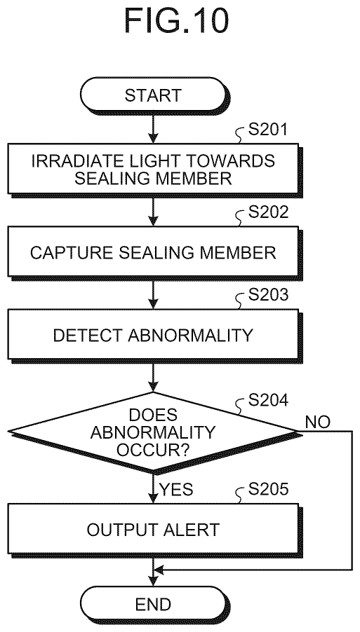

Next, details of substrate processing according to the first embodiment will be explained with reference to FIG. 9. FIG. 9 is a flowchart illustrating a processing procedure for substrate processing to be executed by the substrate processing system 1 according to the first embodiment. FIG. 10 indicates one example of a processing procedure from a time when the wafer W is carried into the liquid processing unit 17 until a time when the wafer W is carried out of the drying process unit 18. Processing procedures illustrated in FIG. 9 are executed in accordance with control by the controller 61.

In the substrate processing system 1, the transfer device 13 first takes out the wafer W housed in the carriers C, and further places the wafer W on the delivery unit 14. Next, after taking out the wafer W from the delivery unit 14, as illustrated in FIG. 9, the transfer device 16 carries the wafer W into the liquid processing unit 17 (Step S101).

In the substrate processing system 1, the liquid processing unit 17 executes liquid processing on the wafer W (Step S102). Specifically, the liquid processing unit 17 executes a cleaning process on a surface of the wafer W with the use of chemical liquid and/or rinse liquid, and then further supplies IPA liquid to the surface of the wafer W so as to execute a liquid-film forming process for forming a liquid film.

In the substrate processing system 1, the liquid-processed wafer W, in other words, the wafer W on which a liquid film is formed is delivered from the liquid processing unit 17 to the transfer device 16 (Step S103).

In the substrate processing system 1, the drying process unit 18 causes the movement mechanism 33a (see FIG. 4) to horizontally move the lid body 33 so as to arrange the holding member 32 not holding the wafer W in the carry-in/carry-out area 182 (Step S104).

In the substrate processing system 1, a sealing member abnormality detecting process is executed (Step S105). Details of the above-mentioned sealing member abnormality detecting process will be mentioned later.

In the substrate processing system 1, the wafer W is carried into the drying process unit 18 (Step S106).

Specifically, the transfer device 16 arranges the wafer W, which is held by a wafer holding mechanism of the transfer device 16, above the holding member 32 that is arranged in the carry-in/carry-out area 182 of the drying process unit 18.

In the substrate processing system 1, the wafer W is delivered from the transfer device 16 to the drying process unit 18 (Step S107).

Specifically, the drying process unit 18 raises the lifter 39 from a standby position to a carry-in/carry-out position so as to raise the wafer W that is held by a wafer holding mechanism of the transfer device 16, and further causes the plurality of lifter pins 39a to support the wafer W. Next, the transfer device 16 retracts the wafer holding mechanism. The drying process unit 18 lowers the plurality of lifter pins 39a so as to cause the holding member 32 to hold the wafer W.

The drying process unit 18 causes the movement mechanism 33a (see FIG. 4) to horizontally move the holding member 32 so as to carry the wafer W into the housing member 31 (Step S108).

In the substrate processing system 1, a supercritical drying process is executed (Step S109). Specifically, the drying process unit 18 brings the liquid-film forming processed wafer W into contact with processing fluid in a supercritical state so as to dry the wafer W.

In the substrate processing system 1, the transfer device 16 carries the wafer W out of the drying process unit 18 (Step S110). Specifically, the transfer device 16 causes a wafer holding mechanism to hold the supercritical drying processed wafer W, and further carries the held wafer W out of the transfer device 16. Next, the transfer device 16 places the wafer W on the delivery unit 14, and the transfer device 13 takes out the wafer W from the delivery unit 14 and further returns the wafer W to the carrier C. Thus, a series of substrate processing ends with respect to the single wafer W.

Next, one example of a specific procedure for a sealing member abnormality detecting process in Step S105 will be explained with reference to FIG. 10. FIG. 10 is a flowchart illustrating one example of a specific procedure for a sealing member abnormality detecting process according to the first embodiment. Before starting the sealing member abnormality detecting process, the lid body 33 is separated from the housing member 31 to be arranged in the carry-in/carry-out area 182 along with the holding member 32 in Step S104 illustrated in FIG. 9.

In a state where the housing member 31 and the lid body 33 are separated from each other, the lighting controller 61a causes the lighting unit 55 to irradiate light towards the sealing member 51 on the lid body 33 (Step S201).

Next, the image capturing controller 61b causes the image capturing unit 56 to capture the sealing member 51 receiving irradiated light (Step S202) so as to acquire a captured image.

In other words, in a state where the holding member 32 not holding the wafer W is arranged in the carry-in/carry-out area 182 along with the lid body 33, the image capturing unit 56 captures the sealing member 51 receiving light irradiated from the lighting unit 55, before the lifter 39 rises from a standby position to a carry-in/carry-out position. Thus, it is possible to prevent reduction in capturing accuracy due to interference of the lifter pins 39a of the lifter 39.

Next, the abnormality detecting unit 61c detects abnormality in the sealing member 51 on the basis of the acquired captured image (Step S203).

In a case where detecting occurrence of abnormality in the sealing member 51 (Step S204: Yes), the abnormality detecting unit 61c outputs an alert (Step S205), and further ends the processing.

On the other hand, in a case where detecting that abnormality has not occurred in the sealing member 51 (Step S204: No), the abnormality detecting unit 61c ends the processing without outputting an alert.

In a case where detecting that abnormality has occurred in the sealing member 51, the abnormality detecting unit 61c may stop executing the supercritical drying process, and further may output an alert. For example, the abnormality detecting unit 61c may stop processes of Step S106 and the following steps illustrated in FIG. 9, and further may output an alert.

In the first embodiment described so far, the example is indicated in which the sealing member 51 is provided to the lid body 33; however, the sealing member 51 may be provided to the surface 31c of the housing member 31.

In the first embodiment, the example is indicated in which abnormality in the sealing member 51 is detected on the basis of the brightness in a captured image that is acquired by the image capturing unit 56 capturing the sealing member 51; however, a method for detecting abnormality in the sealing member 51 is not limited thereto. For example, abnormality in the sealing member 51 may be detected on the basis of a difference image between a captured image and a predetermined reference image stored in the storage 62. Note that the predetermined reference image indicates preliminarily-captured image data of the sealing member 51 and a region around the sealing member 51 in a case where the sealing member 51 is normal, for example.

### Second Embodiment

### Configuration of Drying Process Unit

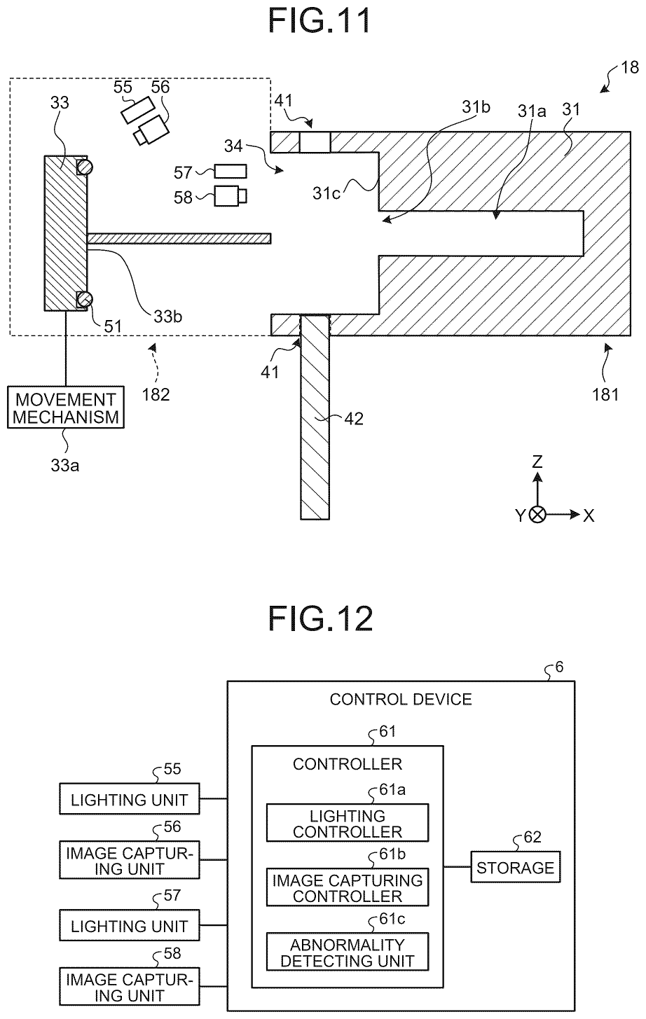

Next, a configuration of the drying process unit 18 according to a second embodiment will be explained with reference to FIG. 11. FIG. 11 is a cross-sectional view illustrating a configuration of the drying process unit 18 according to the second embodiment. Note that FIG. 11 indicates a state where the lid body 33 in the drying process unit 18 is arranged in the carry-in/carry-out area 182.

As illustrated in FIG. 11, the drying process unit 18 further includes a lighting unit 57 (one example of another lighting unit) and an image capturing unit 58 (one example of another image capturing unit).

The lighting unit 57 is arranged in the carry-in/carry-out area 182, and further irradiates light towards a contact target region that is in contact with the sealing member 51 of the housing member 31 in a state where the housing member 31 and the lid body 33 are separated from each other. For example, the lighting unit 57 irradiates light towards the contact target region in the surface 31c of the housing member 31.

The image capturing unit 58 is adjacently arranged to the lighting unit 57 in the carry-in/carry-out area 182 so as to capture a contact target region that receives light irradiated from the lighting unit 57. For example, the image capturing unit 58 captures a contact target region in the surface 31c of the housing member 31, which receives light irradiated from the lighting unit 55.

As described above, the drying process unit 18 causes the image capturing unit 58 to capture a contact target region with the sealing member 51 while causing the lighting unit 57 to light the contact target region with the sealing member 51, so as to detect abnormality in the sealing member 51.

There presents possibility that fluff fallen from the sealing member 51 adheres to a contact target region with the sealing member 51 in the housing member 31, as an adhering substance. If capturing is executed by the image capturing unit 58 without using the lighting unit 57, an interface is not clearly specified between an adhering substance on the surface 31c of the housing member 31 and a region around the adhering substance on the surface 31c. Thus, there presents possibility that specifying an adhering substance (namely, fluff) adhering to a contact target region with the sealing member 51 is difficult.

On the other hand, the drying process unit 18 according to the present embodiment causes the lighting unit 57 to light a contact target region with the sealing member 51 that is a capturing target of the image capturing unit 58. Thus, in the surface 31c of the housing member 31, it is possible to clarify an interface between an adhering substance and a region around the adhering substance on the surface 31c by using a contrast difference between the adhering substance and the region around the adhering substance. As a result, an adhering substance (namely, fluff) adhering to a contact target region with the sealing member 51 can be easily specified, so that it is possible to appropriately detect abnormality in the sealing member 51.

### Configuration of Control Device

Next, a configuration of the control device 6 according to the second embodiment will be explained with reference to FIG. 12. FIG. 12 is a block diagram illustrating a configuration of the control device 6 according to the second embodiment. As illustrated in FIG. 12, the control device 6 is connected to the lighting unit 57 and the image capturing unit 58.

The lighting controller 61a controls the lighting unit 57 to irradiate light irradiated from the lighting unit 57 towards a contact target region with the sealing member 51 of the housing member 31. The image capturing controller 61b controls the image capturing unit 58 captures a contact target region with the sealing member 51 that receives light irradiated from the lighting unit 57, so as to acquire another captured image.

The abnormality detecting unit 61c receives a captured image acquired by the image capturing controller 61b so as to detect abnormality in the sealing member 51 on the basis of the above-mentioned captured image.

The abnormality detecting unit 61c receives another captured image acquired by the image capturing controller 61b so as to detect abnormality in the sealing member 51 on the basis of the above-mentioned captured image.

Specifically, the abnormality detecting unit 61c receives another captured image of a contact target region with the sealing member 51, which is acquired by the image capturing controller 61b, and further executes image processing on the received other captured image by a predetermined method. For example, similar to the case of the captured image, the abnormality detecting unit 61c acquires, for each pixel, a contrast difference that is a differential value of the brightness between adjacent pixel data in the other captured image, and further detects, as an edge on the image, a pixel having the above-mentioned contrast difference that is equal to or higher than a predetermined value.

The abnormality detecting unit 61c determines whether or not an edge is detected, so as to detect abnormality in the sealing member 51. In a case where determining that there presents an adhering substance in a contact target region, the abnormality detecting unit 61c detects occurrence of abnormality in the sealing member 51.

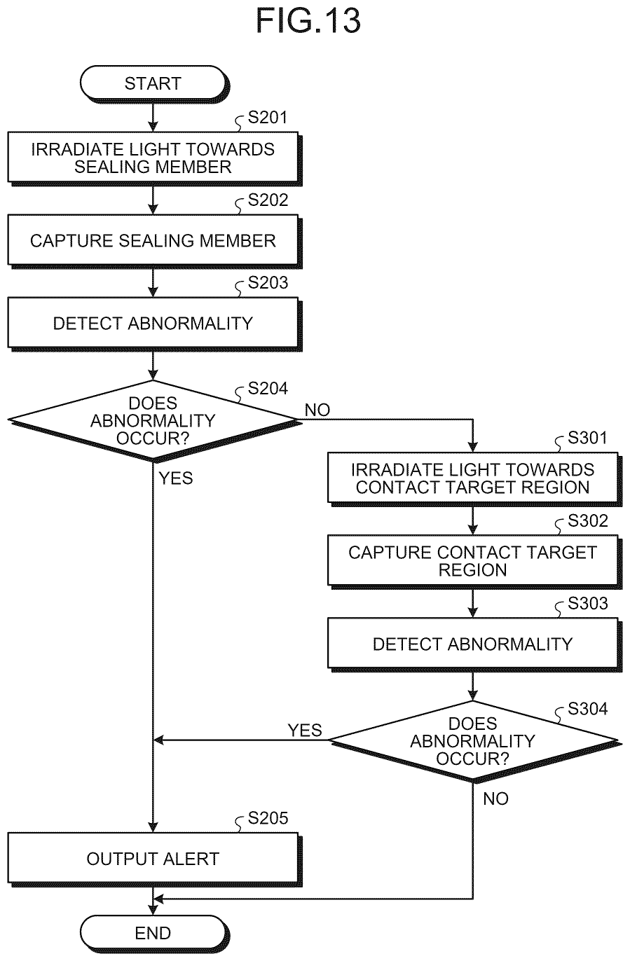

Next, one example of a specific procedure for a sealing member abnormality detecting process according to the second embodiment will be explained with reference to FIG. 13. FIG. 13 is a flowchart illustrating one example of a specific procedure for a sealing member abnormality detecting process according to the second embodiment. Note that before starting the sealing member abnormality detecting process, in Step S104 illustrated in FIG. 9, the lid body 33 is separated from the housing member 31 to be arranged in the carry-in/carry-out area 182 along with the holding member 32.

The abnormality detecting unit 61c detects abnormality in the sealing member 51 on the basis of the acquired captured image (Step S203), and in a case where occurrence of abnormality in the sealing member 51 is not detected (Step S204: No), shifts the processing to Step S301.

In a state where the housing member 31 and the lid body 33 are separated from each other, the lighting controller 61a causes the lighting unit 57 to irradiate light towards a contact target region in the housing member 31 with the sealing member 51 (Step S301).

Next, the image capturing controller 61b causes the image capturing unit 58 to capture the contact target region with the sealing member 51, which receives the irradiated light (Step S302), and further acquires another captured image.

In other words, before the lifter 39 rises from a standby position up to a carry-in/carry-out position in a state where the holding member 32 not holding the wafer W is arranged in the carry-in/carry-out area 182 along with the lid body 33, the image capturing unit 56 captures a contact target region with the sealing member 51 that receives light irradiated from the lighting unit 57. Thus, it is possible to prevent reduction in capturing accuracy due to interference of the lifter pins 39a of the lifter 39.

Next, the abnormality detecting unit 61c detects abnormality in the sealing member 51 on the basis of the other acquired captured image (Step S303).

In a case where detecting occurrence of abnormality in the sealing member 51 (Step S304: Yes), the abnormality detecting unit 61c outputs an alert (Step S205), and further ends the processing.

On the other hand, in a case where detecting that abnormality has not occurred in the sealing member 51 (Step S304: No), the abnormality detecting unit 61c ends the processing without outputting an alert.

Note that in a case where detecting occurrence of abnormality in the sealing member 51, the abnormality detecting unit 61c may stop executing a supercritical drying process so as to output an alert. For example, the abnormality detecting unit 61c may stop the processes of Step S106 and the following illustrated in FIG. 9 so as to output an alert.

In the example illustrated in FIG. 13, Steps S301 to S303 may be executed before Steps S201 to S203. In other words, the abnormality detecting unit 61c may execute an abnormality detection on the sealing member 51 based on another captured image of a contact target region, and in a case where detecting that abnormality has not occurred, may execute an abnormality detection on the sealing member 51 based on a captured image of the sealing member 51.

In the second embodiment described so far, the example is exemplified in which abnormality in the sealing member 51 is detected on the basis of the brightness in another captured image that is acquired by the image capturing unit 58 capturing a contact target region with the sealing member 51; however, a method for detecting abnormality in the sealing member 51 is not limited thereto. For example, abnormality in the sealing member 51 may be detected on the basis of a difference image between another captured image and a predetermined reference image stored in the storage 62. Note that the predetermined reference image indicates image data of a preliminarily-captured contact target region with the sealing member 51 in a case where the sealing member 51 is normal, for example.

### Third Embodiment

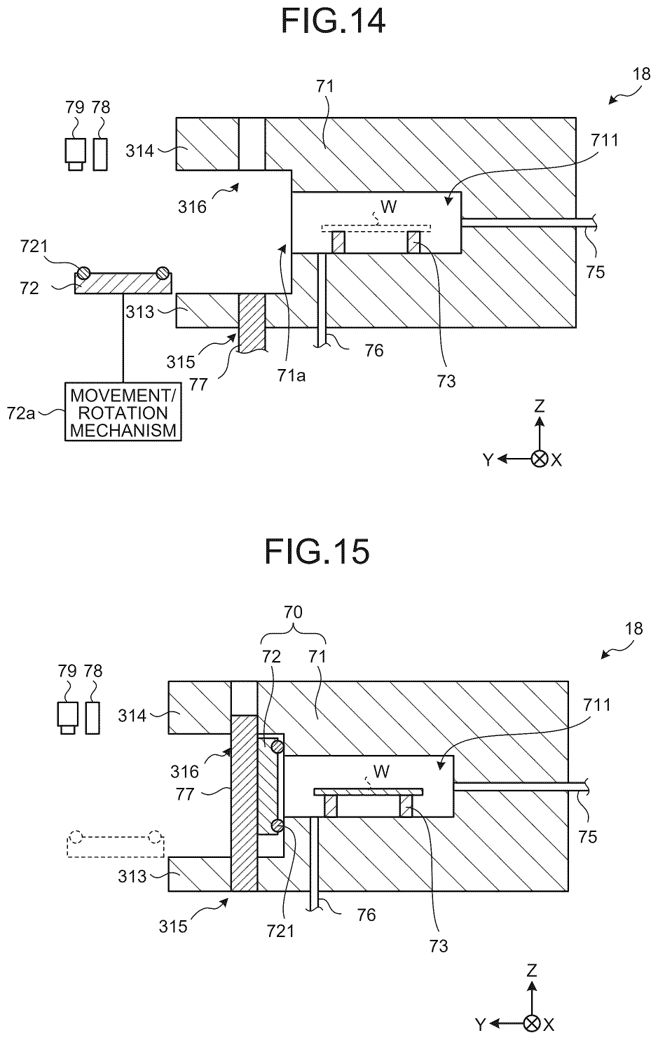

Next, a configuration of the drying process unit 18 according to a third embodiment will be explained with reference to FIG. 14 and FIG. 15. FIG. 14 is a cross-sectional view illustrating a configuration of the drying process unit 18 according to the third embodiment. FIG. 15 is a cross-sectional view illustrating one example of a state where the wafer W is housed in a processing container 70 of the drying process unit 18.

As illustrated in FIG. 14 and FIG. 15, the drying process unit 18 includes the processing container 70 and a support part 73. The processing container 70 includes a housing member 71 (one example of first member) and a lid body 72 (one example of second member) that are capable of connecting with and separating from each other, and further is configured to be capable of forming therein a sealed processing space 711.

The housing member 71 is a housing-shaped housing in which the processing space 711 is formed therein, which is capable of housing therein the wafer W having a diameter of 300 mm, for example, and further is a pressure vessel that is capable of forming a high-pressure environment of approximately 16 MPa to 20 MPa, for example. The housing member 71 is arranged on each of both sides of the transfer area 15 (see FIG. 1) in a Y-axis direction, and a supercritical drying process is executed in the processing space 711 of the housing member 71. The housing member 71 is formed in rectangular parallelepiped in a plan view, and includes an opening 71a (one example of transfer port) to be used when the wafer W is carried-in/out, which is formed on a side surface facing the transfer area 15 among a plurality of side surfaces (herein, four surfaces) thereof.

The lid body 72 is connected with a movement/rotation mechanism 72a so as to move and turn between a closing position and a standby position by the movement/rotation mechanism 72a. The closing position is a position in which the lid body 72 closes the opening 71a. The standby position is a position in which the lid body 72 opens the opening 71a, and further is a position that does not interfere with a carrying-in/out route of the wafer W to the opening 71a.

The support part 73 is arranged in the housing member 71 so as to horizontally support the wafer W from the below. The support part 73 includes support pins that support the wafer W from the below, and is arranged on a bottom surface in the housing member 71.

A supply unit 75 and a discharge unit 76 are arranged in the housing member 71. The supply unit 75 is connected to a supply device group of the supply unit 19 (see FIG. 1) so as to supply processing fluid to the processing space 711, which is supplied from the supply unit 19. The discharge unit 76 discharges processing fluid from the processing space 711.

The supply unit 75 is arranged on a side surface opposite to a side on which the opening 71a of the processing space 711 in the housing member 71 is formed. The supply unit 75 supplies, in a horizontal direction, processing fluid to the processing space 711 from a supplying port that opens in a lateral direction.

The discharge unit 76 is arranged on a bottom surface of the processing space 711 in the housing member 71. The discharge unit 76 discharges processing fluid from a discharge port that opens upward.

The drying process unit 18 discharges processing fluid in the processing space 711 via the discharge unit 76 while supplying processing fluid to the processing space 711 from the supply unit 75. A damper that adjusts a discharging amount of the processing fluid supplied from the processing space 711 is arranged on a discharge path of processing fluid, and a discharging amount of the processing fluid is adjusted by the damper such that a pressure in the processing space 711 is adjusted into a desired pressure. Thus, a supercritical state of the processing fluid is maintained in the processing space 711. Hereinafter, processing fluid in a supercritical state may be referred to as “supercritical fluid”.

The housing member 71 includes a first protruding part 313 and a second protruding part 314 each of which protrudes from the opening 71a in an open-lid direction of the opening 71a. The first protruding part 313 protrudes from a lower portion of the opening 71a in the Y-axis direction, and the second protruding part 314 protrudes from an upper portion of the opening 71a in the Y-axis direction.

In the first protruding part 313, a first insertion hole 315 is formed, which communicates an upper surface and a lower surface of the first protruding part 313 with each other. In the second protruding part 314, a second insertion hole 316 is formed in a position (in other words, above first insertion hole 315) facing the first insertion hole 315 in the vertical direction, which communicates an upper surface and a lower surface of the second protruding part 314 with each other.

The drying process unit 18 includes a locking member 77. The locking member 77 is inserted into the first insertion hole 315 formed in the first protruding part 313. With the locking member 77, a turn/lift mechanism (not illustrated) is connected that is configured to move the locking member 77 in the vertical direction.

In the above-mentioned drying process unit 18, a carrying-in process is first executed on the wafer W. In the carrying-in process, the transfer device 16 delivers the wafer W held by the wafer holding mechanism to the support part 73. The drying process unit 18 moves and turns the lid body 72 arranged in a standby position to an open/close position. Thus, the wafer W supported by the support part 73 is housed in the processing space 711 of the housing member 71, and further goes into a state where the processing space 711 is sealed by the lid body 72.

The drying process unit 18 causes a turn/lift mechanism (not illustrated) to raise the locking member 77 so as to insert the locking member 77 into the second insertion hole 316 formed in the second protruding part 314.

The locking member 77 presses the lid body 72 towards the processing space 711 against an inner pressure that is applied from processing fluid supplied to the processing space 711. Thus, it is possible to maintain a state where the processing space 711 is sealed by the lid body 72.

Next, in the drying process unit 18, a pressure increasing process is executed. In the pressure increasing process, the drying process unit 18 supplies processing fluid to the processing space 711 of the housing member 71 from the supply unit 75, so as to raise a pressure of the processing space 711. Thus, a pressure of the processing space 711 rises from the atmospheric pressure up to a processing pressure. The processing pressure is a pressure that exceeds a critical pressure (namely, approximately 7.2 MPa) at which processing fluid of CO₂ goes into a supercritical state, and is approximately 16 MPa, for example. According to the above-mentioned pressure increasing process, processing fluid in the processing space 711 phase-changes into a supercritical state, and IPA liquid applied to a surface of the wafer W starts to dissolve into the processing fluid in a supercritical state. Note that the processing fluid supplied from the supply unit 19 may be in a supercritical state or a liquid state.

Next, in the drying process unit 18, a flowing process is executed. In the flowing process, the drying process unit 18 discharges processing fluid having been supplied to the processing space 711 from the discharge unit 76 to the outside of the processing space 711 while supplying processing fluid from the supply unit 75 to the processing space 711 and keeping a pressure of the processing space 711 a processing pressure. Thus, in the processing space 711, laminar flow of processing fluid is formed in surroundings of the wafer W, which flows in a predetermined direction.

IPA liquid remaining on a pattern-formed surface (namely, upper surface) of the wafer W is in contact with supercritical fluid in a high-pressure state (for example, 16 MPa) to be gradually dissolved into the supercritical fluid, and is finally replaced with the supercritical fluid. Thus, gaps in a pattern goes into a state being filled with the supercritical fluid.

Next, in the drying process unit 18, a pressure reducing process is executed. In the pressure reducing process, the drying process unit 18 reduces a pressure in the processing space 711 from a high-pressure state to the atmospheric pressure. Thus, the supercritical fluid having filled gaps in a pattern changes into processing fluid that is in a normal state, in other words, a gas state. In this way, IPA liquid between gaps is removed so as to complete the drying process of the wafer W.

Herein, IPA liquid is employed as liquid for preventing drying and CO₂ is employed as processing fluid; however, liquid other than IPA may be employed as the liquid for preventing drying and fluid other than CO₂ may be employed as the processing fluid.

In the housing member 71, the processing space 711, in which the wafer W is processed, and the opening 71a via which the wafer W is transferred into the processing space 711 are formed.

The lid body 72 is in contact with a surface around the opening 71a of the housing member 71 via a sealing member 721 to be connected with the housing member 71. For example, the sealing member 721 is made of resin, and is a member referred to as an “O-ring” formed in O-shaped in a cross-sectional view. The sealing member 721 is not limited to an O-ring, and may be a member referred to as a “U-seal” that is formed in U-shaped in a cross-sectional view, for example.

The sealing member 721 is arranged on a surface of the lid body 72, which is capable of facing a surface around the opening 71a of the housing member 71. The sealing member 721 is arranged so as to surround the opening 71a in a side view. The sealing member 721 is arranged such that an inner surface on a side of the opening 71a communicates with the processing space 711. Thus, the sealing member 721 gradually deteriorates due to an inner pressure that is applied by supercritical fluid supplied to the processing space 711. As a deterioration state of the sealing member 721, for example, there is exemplified a state where a protruding portion (namely, fluff) is formed in a part of a peripheral edge of the sealing member 721 on an inner surface of the sealing member 721 located on a side of the opening 71a.

The drying process unit 18 further includes a lighting unit 78 and an image capturing unit 79.

The lighting unit 78 irradiates light towards the sealing member 721 of the lid body 72 in a state where the housing member 71 and the lid body 72 are separated from each other.

The image capturing unit 79 is adjacently arranged to the lighting unit 78 so as to capture the sealing member 721 that receives light irradiated from the lighting unit 78.

As described above, the drying process unit 18 causes the image capturing unit 79 to capture the sealing member 721 while causing the lighting unit 78 to light the sealing member 721, so as to detect abnormality in the sealing member 721. Thus, it is possible to appropriately detect abnormality in the sealing member 721.

In the present embodiment, the image capturing unit 79 captures the sealing member 721 that receives light irradiated from the lighting unit 78 before the wafer W is transferred to the support part 73 via an opening 51a in a state where the housing member 71 and the lid body 72 are separated from each other. Thus, it is possible to prevent reduction in capturing accuracy due to a carrying-in process of the wafer W.

### Fourth Embodiment

In the above-mentioned first and the second embodiments, a drying process unit is explained, which is one example of a substrate processing apparatus; however, the substrate processing apparatus is not limited to a drying process unit. For example, the substrate processing apparatus may be an ozonated water processing unit that is configured to process the wafer W with the use of ozonated water. In the third embodiment, a case will be explained in which a substrate processing apparatus is an ozonated water processing unit that is configured to process the wafer W with the use of ozonated water.

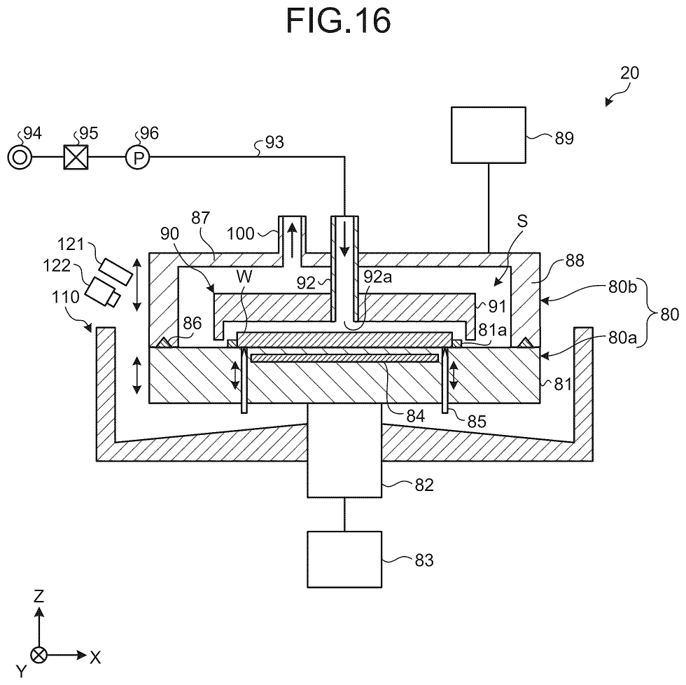

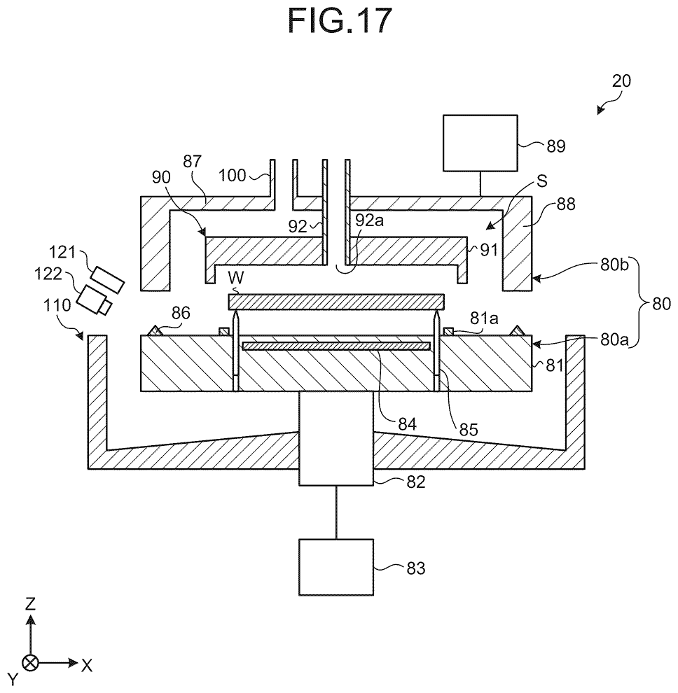

A configuration of an ozonated water processing unit 20 according to the fourth embodiment will be explained with reference to FIG. 16 and FIG. 17. FIG. 16 is a schematic diagram illustrating a configuration example of the ozonated water processing unit 20 according to the fourth embodiment. FIG. 17 is a diagram illustrating a state where a processing container 80 of the ozonated water processing unit 20 according to the fourth embodiment is separated.

As illustrated in FIG. 16 and FIG. 17, the ozonated water processing unit 20 (one example of substrate processing apparatus) includes the processing container 80, a liquid supplying unit 90, a liquid discharging unit 100, and a recovery cup 110. The liquid supplying unit 90 is one example of an ozonated water supplying unit. The liquid discharging unit 100 is one example an ozonated water discharging unit.

The processing container 80 includes a first housing member 80a (one example of first member) and a second housing member 80b (one example of second member) that are capable of connecting with and separating from each other, and is configured to be capable of forming therein a sealed processing space S.

The first housing member 80a includes a placing part 81, a supporting unit 82, a turn/lift mechanism 83, a heater 84, lift pins 85, and a sealing member 86.

The placing part 81 is formed in substantially circular-shaped on which the wafer W is horizontally placed. A bank 81a is arranged in a region of the placing part 81, on which the wafer W is placed. The bank 81a is arranged so as to erect from a periphery portion of the region of the placing part 81, on which the wafer W is placed, and further fixes a position of the wafer W while being in contact with an edge portion of the wafer W.

The supporting unit 82 is a member extending in the vertical direction, a bottom end thereof is supported by the turn/lift mechanism 83 to be movable in the vertical direction, and further horizontally supports the placing part 81 in a leading end thereof. The turn/lift mechanism 83 moves the supporting unit 82 in the vertical direction.

The above-mentioned first housing member 80a causes the turn/lift mechanism 83 to move the supporting unit 82 in the vertical direction so as to move the placing part 81 supported by the supporting unit 82 in the vertical direction.

The heater 84 is a plane-shaped heater arranged in the placing part 81 so as to heat the wafer W up to a predetermined temperature, which is housed in the processing space S of the second housing member 80b.

The lift pins 85 are arranged so as to penetrate through the placing part 81, and further is configured to be movable upward or downward by a not-illustrated turn/lift mechanism.

The lift pins 85 supports the above-mentioned wafer W (see FIG. 17) when the wafer W is placed on the placing part 81. For example, the three lift pins 85 are arranged in the placing part 81, and further are arranged at intervals of 120 degrees along a circumferential direction.

The sealing member 86 is arranged so as to erect from whole of a periphery portion of the placing part 81. In a case where the first housing member 80a and the second housing member 80b are connected with each other, the sealing member 86 is in contact with the second housing member 80b so as to seal the processing space S of the second housing member 80b. As the sealing member 86, for example, an O-ring, metal gasket, etc. may be employed.

The second housing member 80b includes a sealing portion 87 facing the placing part 81, and a side wall portion 88 extending downward from the sealing portion 871. An opening is formed in a lower portion of the second housing member 80b by the sealing portion 87 and the side wall portion 88 so as to form a substantially cylindrical-shaped part forming therein the processing space S.

A turn/lift mechanism 89 is connected with the second housing member 80b. The turn/lift mechanism 89 moves the second housing member 80b in the vertical direction.

The processing container 80 having been explained so far causes the turn/lift mechanisms 83 and 89 to move the placing part 81 and the second housing member 80b in carrying in and carrying out the wafer W to be capable of separating the placing part 81 and the second housing member 80b from each other as illustrated in FIG. 17. In a state where the placing part 81 and the second housing member 80b are separated from each other, an opening of the second housing member 80b is opened, and the wafer W is transferred between the lift pins 85 and a substrate transfer device (not illustrated) via a gap between the placing part 81 and the second housing member 80b.

On the other hand, in processing the wafer W, the processing container 80 causes the turn/lift mechanisms 83 and 89 to move the placing part 81 and the second housing member 80b, and brings the second housing member 80b into contact with the placing part 81 so as to close an opening of the second housing member 80b as illustrated in FIG. 16. Thus, the first housing member 80a and the second housing member 80b are connected with each other so as to form the sealed processing space S in the processing container 80.

The liquid supplying unit 90 is arranged in the sealing portion 87 of the second housing member 80b so as to supply ozonated water to the processing space S. The liquid supplying unit 90 includes a covering member 91, which covers the wafer W placed in the placing part 81, and a supply pipe 92 provided to the covering member 91.

The supply pipe 92 is connected to an ozonated water supplying route 93. The ozonated water supplying route 93 supplies ozonated water to the supply pipe 92. The ozonated water supplying route 93 includes an ozonated water generating unit 94, a valve 95, and a pump 96 (one example of pressurizing unit) in this order from an upstream side thereof.

The ozonated water generating unit 94 generates ozonated water having a predetermined ozone concentration. For example, the above-mentioned “predetermined ozone concentration” is an ozone concentration at which a resist film formed on the wafer W can be removed (namely, released), and is within a range from 0 mg/L to 1500 mg/L, for example.

The valve 95 is a valve that opens/closes the ozonated water supplying route 93.

The pump 96 pressurizes ozonated water flowing through the ozonated water supplying route 93 up to a pressure that is higher than the atmospheric pressure. Thus, it is possible to efficiently generate ozonated water having the predetermined ozone concentration.

The supply pipe 92 includes a supplying port 92a that is arranged in a position of the covering member 91 corresponding to a central portion of the wafer W. The supply pipe 92 supplies ozonated water towards a central portion of the wafer W from the supplying port 92a. Thus, in a gap between the covering member 91 and the wafer W, a flow of ozonated water is formed, which is flowing form a central portion of the wafer W to a peripheral portion of the wafer W, along a bottom surface the covering member 91.

The liquid discharging unit 100 is arranged in the sealing portion 87 of the second housing member 80b. The liquid discharging unit 100 discharges ozonated water, which is supplied from the liquid supplying unit 90 to the processing space S and further has passed through the processing space S, to the outside of the processing container 80.

The recovery cup 110 is arranged so as to surround the placing part 81, and further collects processing liquid flowing out from a gap between the placing part 81 and the second housing member 80b when the placing part 81 and the second housing member 80b are separated from each other. In a bottom portion of the recovery cup 110, a not-illustrated drain port is formed, and processing liquid collected by the recovery cup 110 is discharged from the above-mentioned drain port to the outside of the ozonated water processing unit 20.

In processing the wafer W in the ozonated water processing unit 20 having been explained so far, the wafer W is first placed on the placing part 81 of the first housing member 80a. Next, the turn/lift mechanisms 83 and 89 moves the placing part 81 and the second housing member 80b so as to close an opening of the second housing member 80b. Thus, the processing space S of the second housing member 80b is sealed.

Next, the liquid supplying unit 90 supplies ozonated water to the sealed processing space S so as to fill the processing space S with the ozonated water.

Herein, in the present embodiment, in a state where the processing space S is filled with ozonated water, the ozonated water is pressurized by the pump 96 on an upper stream side than the liquid supplying unit 90 so as to increase a supplying pressure of ozonated water to the processing space S. Thus, ozonated water in the processing space S is pressurized up to a pressure that is higher than the atmospheric pressure, for example, so that it is possible to prevent a case where an ozone concentration of ozonated water around the wafer W decreases due to reduction in a pressure of the ozonated water in the processing space S.

In other words, in the present embodiment, ozonated water in the processing space S is highly pressurized to be able to maintain a concentration of the ozonated water around the wafer W.

Thus, according to the present embodiment, it is possible to efficiently process the wafer W with the use of ozonated water.

In the present embodiment, the wafer W is covered by the covering member 91 of the liquid supplying unit 90, and further ozonated water is supplied to the wafer W from the supply pipe 92 provided to the covering member 91. Thus, a gap between the wafer W and the covering member 91 can be filled with non-deactivated fresh ozonated water, so that it is possible to more efficiently process the wafer W with the use of ozonated water.

In the present embodiment, the supply pipe 92 supplies ozonated water to a central portion of the wafer W from the supplying port 92a that is arranged in a position of the covering member 91 corresponding to the central portion of the wafer W. Thus, in a gap between the covering member 91 and the wafer W, a flow of ozonated water is formed, which flows from a central portion of the wafer W towards a peripheral portion of the wafers W along a bottom surface of the covering member 91 so that bubbles are excluded from a gap between the covering member 91 and the wafer W by the above-mentioned flow of ozonated water.

Thus, according to the present embodiment, it is possible to prevent decrease in a processing performance of the wafer W due to bubbles in ozonated water.

Incidentally, in the ozonated water processing unit 20, the sealing member 86 gradually deteriorates due to an inner pressure applied by ozonated water supplied to the processing space S. For example, as a deterioration state of the sealing member 86, a state is exemplified where a protruding portion (namely, fluff) is formed on a part of a peripheral edge of the sealing member 86 on an inner surface of the sealing member 86.

Thus, the ozonated water processing unit 20 further includes a lighting unit 121 and an image capturing unit 122.

The lighting unit 121 irradiates light towards the sealing member 86 in the first housing member 80a in a state where the first housing member 80a and the second housing member 80b are separated from each other.

The image capturing unit 122 is adjacently arranged to the lighting unit 121 so as to capture the sealing member 86 that receives light irradiated from the lighting unit 121.

As described above, the ozonated water processing unit 20 causes the image capturing unit 122 to capture the sealing member 86 while causing the lighting unit 121 to light the sealing member 86, so as to detect abnormality in the sealing member 86. Thus, it is possible to appropriately detect abnormality in the sealing member 86.

### Others

In the above-mentioned embodiments, the numbers of the lighting units (for example, lighting units 55, 57, 78, and 121) and the image capturing units (for example, image capturing units 56, 58, 79, and 122) are not particularly limited. For example, one or a plurality of lighting units may be provided. For example, one or a plurality of image capturing units may be provided.

Any of the lighting units (for example, lighting unit 55, 57, 78, and 121) and the image capturing units (for example, the image capturing unit 56, 58, 79, and 122) may be connected with a not-illustrated movement mechanism(s), and may be configured to move between a standby position and a capturing position for capturing by the movement mechanism.

As described above, a substrate processing apparatus (for one example, drying process unit 18 or ozonated water processing unit 20) according to the embodiments includes a processing container (for one example, processing container 30, 70, or 80), a sealing member (for one example, sealing member 51, 86, or 721), a lighting unit (for one example, lighting unit 55, 78, or 121), and an image capturing unit (for one example, image capturing unit 56, 79, or 122). The processing container includes a first member (for one example, housing member 31 or 71, or first housing member 80a) and a second member (for one example, lid body 33 or 72) that can be connected with each other, and moves the second member to be connected with the first member to form therein a processing space (for one example, processing space 31a, 711, or S) in which a substrate (for one example, wafer W) is processed. The sealing member is provided to one of the first member and the second member, and is in contact with another of the first member and the second member in a case where the first member and the second member are connected with each other. The lighting unit irradiates light towards the sealing member on the one of the first member and the second member in a state where the first member and the second member are separated from each other. The image capturing unit captures the sealing member that receives the light irradiated from the lighting unit. Thus, it is possible to appropriately detect abnormality in the sealing member.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

According to the present disclosure, it is possible to appropriately detect abnormality in a sealing member.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A substrate processing apparatus comprising:
a processing container that includes a first member and a second member that can be connected with each other, and moves the second member to be connected with the first member to form therein a processing space in which a substrate is processed;
a sealing member that is provided to one of the first member and the second member, and is in contact with another of the first member and the second member in a case where the first member and the second member are connected with each other;
a lighting unit that irradiates light towards the sealing member on the one of the first member and the second member in a state where the first member and the second member are separated from each other; and
an image capturing unit that captures the sealing member that receives the light irradiated from the lighting unit.

2. The substrate processing apparatus according to claim 1 further comprising:
an abnormality detecting unit that detects abnormality in the sealing member based on a captured image acquired by the image capturing unit capturing the sealing member.

3. The substrate processing apparatus according to claim 2, wherein
based on a brightness in the captured image, the abnormality detecting unit specifies a protruding portion that protrudes from a peripheral edge of the sealing member, and in a case where a length of the specified protruding portion is equal to or more than a threshold, detects occurrence of abnormality in the sealing member.

4. The substrate processing apparatus according to claim 2 further comprising:
another lighting unit that irradiates light towards a contact target region of the other of the first member and the second member, the contact target region being to come in contact with the sealing member, in a state where the first member and the second member are separated from each other; and
another image capturing unit that captures the contact target region that receives light irradiated from the other lighting unit, wherein
the abnormality detecting unit detects abnormality in the sealing member based on another captured image that is acquired by the other image capturing unit capturing the contact target region.

5. The substrate processing apparatus according to claim 4, wherein
the abnormality detecting unit determines presence/absence of an adhering substance in the contact target region based on a brightness in the other captured image, and in a case where determining that the adhering substance is present in the contact target region, detects occurrence of abnormality in the sealing member.

6. The substrate processing apparatus according to claim 2, wherein
in a case where detecting occurrence of abnormality in the sealing member, the abnormality detecting unit outputs an alert.

7. The substrate processing apparatus according to claim 1, wherein
the first member includes a housing member in which the processing space and a transfer port to the processing space are formed, in the processing space the substrate being processed by using processing fluid,
the second member includes a lid body that is capable of opening/closing the transfer port,
the sealing member is provided to one of the housing member and the lid body to circularly surround the transfer port, and
the processing container includes a processing container in which the substrate, on whose surface a liquid film is formed, is in contact with the processing fluid in a supercritical state to execute a drying process for drying the substrate.

8. The substrate processing apparatus according to claim 7 further comprising:
a pressing member that presses the lid body towards the processing space against an inner pressure generated by the processing fluid in a supercritical state which is supplied to the processing space in the housing member.

9. The substrate processing apparatus according to claim 7 further comprising:
a holding member that is provided to the lid body to hold the substrate; and
a movement mechanism that moves the holding member between a carry-in/carry-out area adjacent to the housing member and an inner part of the housing member, wherein
the lighting unit and the image capturing unit are arranged in the carry-in/carry-out area.

10. The substrate processing apparatus according to claim 9 further comprising:
a lifter that is arranged in the carry-in/carry-out area, and includes a substrate supporting pin; and
a turn/lift mechanism that turns/lifts the lifter between a carry-in/carry-out position and a standby position, in the carry-in/carry-out position the substrate being transferred between the substrate supporting pin and a substrate transfer device, and in the standby position the substrate supporting pin being arranged below the holding member, wherein
in a state where the holding member not holding the substrate is arranged in the carry-in/carry-out area along with the lid body, before the lifter rises from the standby position up to the carry-in/carry-out position, the image capturing unit captures the sealing member that receives light irradiated from the lighting unit.

11. The substrate processing apparatus according to claim 7 further comprising:
a support part that is arranged in the housing member to support the substrate from a below, wherein
in a state where the housing member and the lid body are separated from each other, before the substrate is transferred to the support part via the transfer port, the image capturing unit captures the sealing member that receives light irradiated from the lighting unit.

12. The substrate processing apparatus according to claim 1 further comprising:
an ozonated water supplying unit that supplies ozonated water to the processing space;
an ozonated water discharging unit that discharges the ozonated water from the processing space; and
a pressurizing unit that pressurizes the ozonated water on an upper stream side than the ozonated water supplying unit.

13. An abnormality detecting method of a sealing member in a substrate processing apparatus comprising: a processing container that includes a first member and a second member that can be connected with each other, and moves the second member to be connected with the first member to form therein a processing space in which a substrate is processed; a sealing member that is provided to one of the first member and the second member, and is in contact with another of the first member and the second member in a case where the first member and the second member are connected with each other; a lighting unit that irradiates light towards the sealing member on the one of the first member and the second member in a state where the first member and the second member are separated from each other; and an image capturing unit that captures the sealing member that receives the light irradiated from the lighting unit, the method comprising:
in a state where the first member and the second member are separated from each other, causing the lighting unit to irradiate light towards the sealing member in the one of the first member and the second member;
causing the image capturing unit to capture the sealing member that receives the irradiated light; and
based on a captured image that is captured by the image capturing unit, detecting abnormality in the sealing member.
